(19) United States
(12) Patent Application Publication
(10) Pub. No.: US 2008/0164059 A1
(43) Pub. Date: Jul. 10, 2008

(54) METHOD AND SYSTEM OF FEEDING CABLE THROUGH AN ENCLOSURE WHILE MAINTAINING ELECTROGNETIC SHIELDING

(75) Inventor: Thomas M. Cipolla, Katonah, NY (US)

Correspondence Address: CANTOR COLBURN LLP-IBM YORKTOWN, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/620,151

(22) Filed: Jan. 5, 2007

(51) Int. Cl. H05K 9/00; H02G 3/22

(52) U.S. Cl. 174/360; 174/657

(57) ABSTRACT

An exemplary embodiment disclosed herein relates to a method of feeding cable through a wall. The method includes, cutting an outer jacket of a cable, and pulling the outer jacket away from the cut thereby exposing an electromagnetic interference shielding layer. The method further includes, clamping a conductor around the shielding layer, securing the clamped conductor to a conductive wall, and electrically connecting the clamped conductor to the conductive wall.

### GOVERNMENT INTEREST

This invention was made with Government support under contract No.: B517552 awarded by The Department of Energy. The Government has certain rights in this invention.

IBM ® is a registered trademark of International Business Machines Corporation, Armonk, N.Y., U.S.A. Other names used herein may be registered trademarks, trademarks or product names of International Business Machines Corporation or other companies

### BACKGROUND OF THE INVENTION

Electromagnetic Interference or EMI is electromagnetic radiation which is emitted by electrical circuits carrying rapidly changing signals, as a by-product of their normal operation, and which causes unwanted signals (interference or noise) to be induced in other circuits. This interrupts, obstructs, or otherwise degrades or limits the effective performance of those other circuits. Electromagnetic Interference is also known as Radio Frequency Interference or RFI.

Most countries have legal requirements that electronic and electrical hardware must still work correctly when subjected to certain amounts of EMI, and should not emit EMI which could interfere with other equipment (such as radios).

One way to control or contain EMI within a device is to contain the entire electronic device in a conductive enclosure also known as a Faraday cage. Many electronic devices are contained in a single enclosure for which containing the EMI is more easily accomplished by either enclosure in a box made of conductive material or, by adding a conductive layer such as paint, to the inside of the enclosure.

When electronic devices are contained in several different enclosures and are connected by one or more cables, containment of EMI can be difficult. The conductors in the cables may be wrapped in a conductive foil, such as aluminum, for example, or a braided conductor. Both the conductive foil and the braided conductor are known as shields. Effectively connecting the shield of each cable to each conductive enclosure, to which it is connected, in a cost effective system consuming a minimum amount of area around the cable to enclosure interface may be desirable in the art.

### BRIEF DESCRIPTION OF THE INVENTION

An exemplary embodiment disclosed herein relates to a method of feeding cable through a wall. The method includes, cutting an outer jacket of a cable, and pulling the outer jacket away from the cut thereby exposing an electromagnetic interference shielding layer. The method further includes, clamping a conductor around the shielding layer, securing the clamped conductor to a conductive wall, and electrically connecting the clamped conductor to the conductive wall.

Further disclosed herein is an embodiment of a method of electromagnetic interference shielding a cable protruding through a wall of an enclosure. The method includes, circumferentially cutting a jacket radially outward of an electromagnetic interference shielding layer of the cable, and thereby exposing the shielding layer by sliding the jacket away from the circumferential cut. Further, clamping the circumference of the shielding layer with an electrically conductive clamp. And finally, electrically attaching the conductive clamp flush with a wall of an enclosure through which the cable is routed.

Further disclosed herein relates to a system for electromagnetic interference (EMI) shielding a cable through an enclosure wall. The system includes, at least one cable with an electromagnetic shielding layer exposed by a circumferential cut through an outer jacket thereof, and at least one layer of conductive tape with conductive adhesive wrapped circumferentially around the exposed shielding layer. The system further includes, at least one electrically conductive clamp electrically connected to and clamped around the circumference of the tape wrapped cable, and an electrically conductive wall of an enclosure with an opening, the opening being receptive of the cable and the wall being receptive of the at least one conductive clamp.

### BRIEF DESCRIPTION OF THE DRAWINGS

The following descriptions should not be considered limiting in any way. With reference to the accompanying drawings, like elements are numbered alike:

FIG. 1 depicts a partial cross sectional view through a cable, clamp, and wall as disclosed herein; and

FIG. 2 depicts a perspective view of several cables assembled through clamps and a wall as disclosed herein.

### DETAILED DESCRIPTION OF THE INVENTION

A detailed description of several embodiments of the disclosed apparatus and method are presented herein by way of exemplification and not limitation with reference to the Figures.

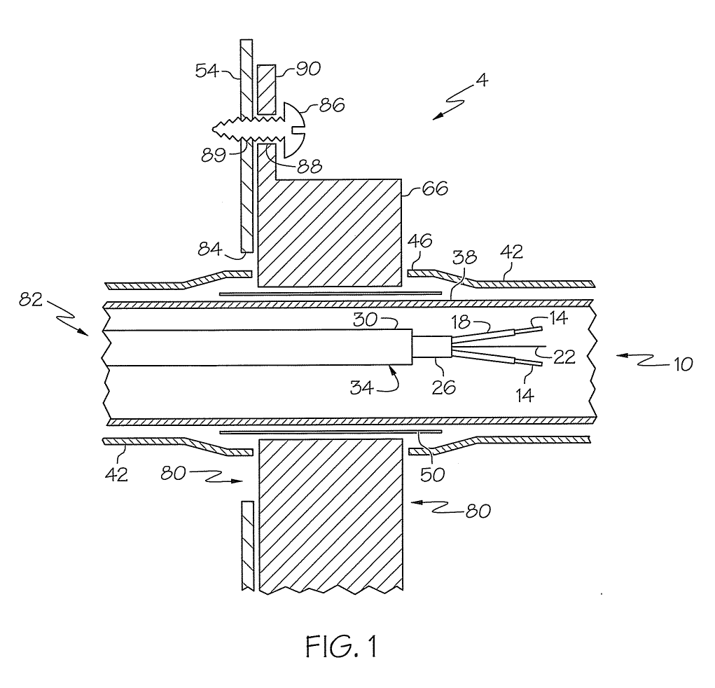

Referring to FIG. 1 an exemplary embodiment disclosed herein of a cable to enclosure interface system is shown generally at 4. A cable 10 includes a plurality of signal conductors 14 each with insulation 18 thereon. A ground wire 22 is coupled with a pair of signal conductors 14 and is encased by a signal shield 26 and a jacket 30 comprising a shielded pair 34. A cable shield 38 and an outer jacket 42 encircle a plurality of shielded pairs 34 (only one pair is shown) to complete the construction of the cable 10. Alternate cable constructions with an outer jacket and EMI shielding layer could also be employed within the scope and spirit of the present invention.

The cable shield 38 minimizes EMI from escaping from the cable 10 or intruding into the cable 10 where it could interfere with the signals traveling through the signal conductors 14. The maximum size of an opening in the shield 38 necessary to effectively block EMI depends on the frequency of the signals. Many computers today operate in the multiple-gigahertz range, and the maximum opening size at these frequencies is on the order of three or four millimeters. Cable shields 38 are frequently made of braided conductor such as aluminum or copper, for example, and are susceptible to damage when not protected by the outer jacket 42.

In an embodiment disclosed herein, a circumferential cut 46 through the outer jacket 42 is pulled back to expose a portion of the cable shield 38. An option to prevent fraying of the shield 38, which may have been inadvertently cut, during the cutting of the outer jacket 42, for example, is to apply a layer of conductive tape 50 over the exposed shield 38. Wrapping at least one full layer of conductive tape 50 around the exposed shield 38 should provide sufficient protection to the shield 38. The conductive tape 50 makes electrical connection with the cable shield 38 to form an EMI shield therearound to minimize EMI leakage should an opening in the exposed shield 38 be formed. The tape 50 also presents a more professional and finished look as compared to the shield layer 38 without the tape 50. Copper foil and metalized fabric are a few possible material choices for the tape 50. The tape 50 may use an adhesive that is conductive to assist in establishing a good electrical connection between the shield 38 and the tape 50.

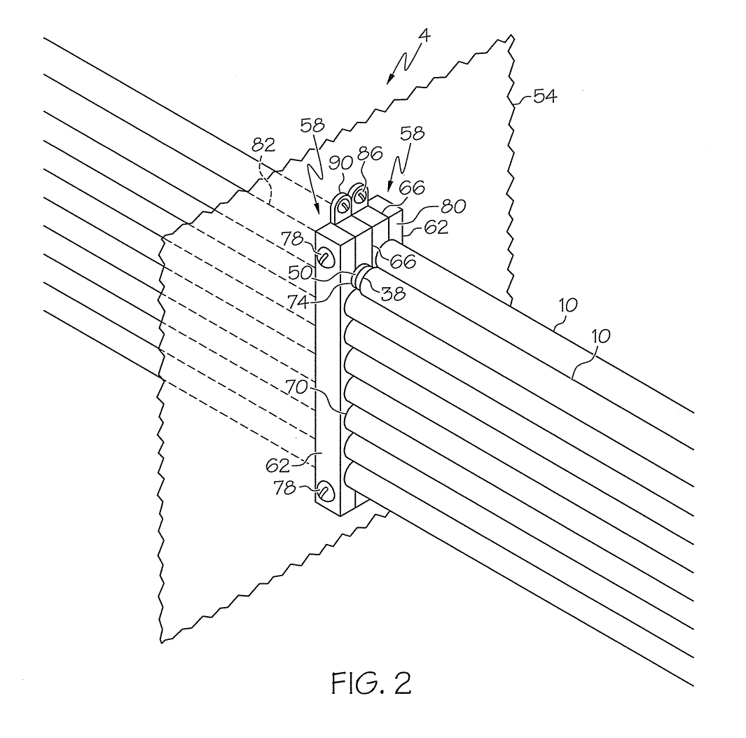

Referring to FIG. 2 a plurality of cables 10 are shown passing through an opening in a wall 54 of an enclosure that contains an electrical circuit (not shown) to which the cables 10 are functionally attached. A pair of electrically conductive clamps 58 each comprising a first portion 62 and a second portion 66 are shown abutting the wall 54. The first portions 62 and the second portions 66 each have a plurality of substantially semicircular grooves 70 that form a substantially circular hole 74 through the clamps 58 when the first portions 62 and the second portions 66 are clamped together. The hole 74 is sized to be slightly smaller in diameter than the diameter formed by the tape 50 around the shield 38 to thereby create a compressive force circumferentially therearound. The compressive force helps to complete the electrical connection between the clamps 58 and the tape 50 and to minimize the size of any openings that could allow EMI to leak therethrough.

The first portion 62 and second portion 66 of the clamps 58 are held together by screws 78 that pass through clearance holes in the first portions 62 and threadably engage with tapped holes (not shown) in the second portions 66. The two clamps 58 shown are reversed end to end from one another such that the screws 78 on one clamp 58 are directed inwardly towards the screws 78 on the other clamp 58. This orientation allows the clamps 58 to lie flush together at the surfaces where they meet. Alternate embodiments may be employed to fasten the first portion 62 and second portion 66 together such as adhesive bonding or click tabs with windows, for example. Additionally, alternate embodiments could clamp any number of cables in any number of rows and columns.

After the screws 78 of the clamps 58 are tightened the outer jacket 42 can be pushed towards the clamps 58 until the outer jacket 42 butts against a surface 80 of the clamp 58 from which the cable 10 extends. Similarly on the opposite side of the clamp 58 the outer jacket 42 can be butted against the surface 80 thereon. Next the clamps 58 are attached to the wall 54. A cable 82 on the wall 54 side of the clamps 58 are fed through openings 84 in the wall 54 until the surfaces 80 of the clamps 54 are flush against the wall 54. Screws 86 protrude through holes 88 in tabs 90 that extend from both ends of the clamps 58 and threadably engage with holes 89 in the wall 54. In addition to mechanically securing the clamps 58 to the wall 54, the screws 86 also complete an electrical circuit that includes the wall 54, the screws 86, the clamps 58, the conductive tape 50, tape adhesive, and EMI shielding 38. By electrically connecting all these components to one another and limiting the size of any openings between them, the cables 10 to wall 54 connections disclosed herein effectively shield the signal conductors 14 within the cable 10 from external EMI, as well as preventing the signal conductors 14 from transmitting potentially damaging EMI energy into the environment.

While the invention has been described with reference to an exemplary embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the claims.

What is claimed is:

1. A method of feeding cable through a wall, comprising:
cutting an outer jacket of a cable;
pulling the outer jacket away from the cut thereby exposing an electromagnetic interference shielding layer;
clamping a conductor around the exposed shielding layer;
securing the clamped conductor to a conductive wall; and
electrically connecting the clamped conductor to the conductive wall.

2. The method of claim 1, further comprising:
taping the exposed shielding layer with electrically conductive tape.

3. The method of claim 2, wherein the taping includes applying more than one full revolution and less than two full revolutions around the cable.

4. The method of claim 2, wherein the tape has electrically conductive adhesive.

5. The method of claim 1, further comprising:
contacting electrically the circumference of the exposed shielding layer with the conductive clamp.

6. The method of claim 1, further comprising:
extending the cable through an opening in the wall prior to securing the clamped conductor to the wall.

7. The method of claim 1, wherein the wall forms an exterior surface of an enclosure.

8. The method of claim 1, further comprising:
sliding the jacket relative to the shielding layer to butt the jacket against the clamped conductor.

9. The method of claim 1, wherein the cutting of the outer jacket is performed circumferentially.

10. The method of claim 1, wherein the cutting of the outer jacket leaves intact the shielding layer radially inward of the outer jacket.

11. A method of electromagnetic interference shielding a cable protruding through a wall of an enclosure, the method comprising:
circumferentially cutting a jacket radially outward of an electromagnetic interference shielding layer of the cable;
exposing the shielding layer by sliding the jacket away from the circumferential cut;
clamping the circumference of the shielding layer with an electrically conductive clamp; and
electrically attaching the conductive clamp flush with a wall of an enclosure through which the cable is routed.

12. The method of claim 11, further comprising:
taping the exposed shielding layer by wrapping electrically conductive tape with electrically conductive adhesive at least one full revolution circumferentially around the exposed shielding layer;

13. The method of claim 12, further comprising:
sliding the jacket over the tape and butting the jacket against the conductive clamp.

14. The method of claim 12, further comprising:
covering with the tape the exposed shielding layer for a greater axial distance than does the conductive clamp.

15. A system for electromagnetic interference (EMI) shielding a cable through an enclosure wall, the system comprising:
at least one cable with an electromagnetic shielding layer exposed by a circumferential cut through an outer jacket thereof;
at least one layer of conductive tape with conductive adhesive wrapped circumferentially around the exposed shielding layer;
at least one electrically conductive clamp electrically connected to and clamped around the circumference of the tape wrapped cable; and
an electrically conductive wall of an enclosure with an opening, the opening being receptive of the cable and the wall being receptive of the at least one conductive clamp.

16. The system of claim 15, wherein the cable includes a plurality of signal conductors.

17. The system of claim 15, wherein the conductive tape is copper foil.
